(19) United States
(12) Patent Application Publication
(10) Pub. No.: US 2026/0126718 A1
(43) Pub. Date: May 7, 2026

(54) Hybrid Inverse Lithography Technology Optimization

(71) Applicant: GDM Holding LLC, Mountain View, CA (US)

(72) Inventors: Abdalaziz I.M. Awad, Mountain View, CA (US); Cyrus Behroozi, Menlo Park, CA (US)

(21) Appl. No.: 19/339,440

(22) Filed: Sep. 25, 2025

Related U.S. Application Data
(60) Provisional application No. 63/716,834, filed on Nov. 6, 2024.

(51) Int. Cl. G03F 1/70; G06F 30/20

(52) U.S. Cl. CPC G03F 1/70; G06F 30/20

(57) ABSTRACT

The technology includes hybrid inverse lithography technology (ILT) optimization. According to one aspect, a method includes obtaining a target mask design for a semiconductor device to be fabricated. Based on a machine learning inverse lithography technology (ML ILT) model, a predicted ILT mask design corresponding to the target mask design is determined. An ILT optimization, using the predicted ILT mask design as an initialization point, is performed. Based on completion of the ILT optimization, a mask design is determined in order to fabricate the semiconductor device.

### CROSS REFERENCE TO RELATED APPLICATIONS

The present application claims the benefit of and priority to U.S. Provisional Application No. 63/716,834, filed Nov. 6, 2024, the entire disclosure of which is hereby incorporated herein by reference.

### BACKGROUND

Improving semiconductor processes and systems, and increasing yield from semiconductor processes and systems, may include modeling of many, if not all, processing steps associated with these semiconductor processes and systems. One such semiconductor process is lithography. Non-limiting examples of lithography processing steps include exposure, resist development, and mask-writing. Existing approaches may be subject to noise, optical diffraction, diffusion, and other lithography-related issues. This can create issues during fabrication of semiconductor devices, including those having large mask designs for advanced technology nodes.

### SUMMARY

Inverse lithography technology (ILT) optimizations may be crucial for achieving viable semiconductor yield in advanced technology nodes. Lithography processes for these advanced technology nodes may have increasingly smaller process windows and/or increasingly problematic optical proximity effects. Conventional ILT optimizations can generate mask designs that are robust and manufacturable. Such optimizations may inversely optimize lithographic printing simulations by, for example, back propagating gradients of simulated loss with respect to a mask design (e.g., a perturbed mask design). Conventional ILT optimizations may be efficient for smaller mask designs. However, computational costs and/or inefficient scaling are challenges associated with using ILT models for advanced technology nodes.

Requirements of a full simulation of mask designs for each step makes conventional ILT optimizations inefficient for scaling to larger mask designs. For instance, a complete conventional ILT optimization of mask designs for a large circuit layout (e.g., a full chip) may take several days, or even weeks, to perform using a significant amount of computer processing resources. Thus, such approaches are impractical for full chips due to weeks-long runtimes and the need for many accelerators to scale in parallel.

Aspects of the technology disclosed herein include a hybrid approach to ILT optimization that leverages machine learning (ML) ILT models to improve the accuracy of ILT optimizations and/or increase acceleration to convergence of ILT optimizations. ML ILT models can be implemented, for example, using an image translation architecture (e.g., a U-Net or other neural network architecture). By way of example, a ML ILT model can be implemented using a convolutional neural network (CNN), a computer vision-oriented neural network, or a set of vision transformers. Mask designs output by trained ML ILT models, which can be output in just milliseconds, can be used to initialize subsequent ILT optimizations. Technical benefits of the disclosed technology include providing reduced (e.g., significantly reduced) computational requirements (e.g., computational resources, runtimes) relative to conventional ILT optimizations alone.

Typical ILT optimizations are initialized with target mask designs, which are considerably far from mask designs ultimately generated by the ILT optimizations. In contrast, the disclosed technology uses ML ILT models to, in effect, replace initial iterations (e.g., the initial tens or hundreds of iterations) that would otherwise need to be performed. That is, the ML ILT models are trained to predict mask designs similar to mask designs that the ILT optimizations would have generated after those “replaced” iterations. Mask designs output by ML ILT models are also referred to herein as “predicted ILT mask designs”. Trained ML ILT models can output predicted ILT mask designs in a mere fraction of the time that it would take to perform those “replaced” iterations with accuracy. Initialization of ILT optimizations with predicted ILT mask designs reduces how many subsequent iterations of the ILT optimizations are performed. Even with the reduced quantity of iterations, the generated mask designs satisfy accuracy criteria. For example, how many iterations of the ILT optimizations are performed can be reduced by a factor of three. This is a significant technical benefit for the computing technology, as it reduces not only the amount of time required to generate a target design, but also reduces the amount of processing power and/or processing resources that would be required.

The disclosed technology can include training ML ILT models using target mask designs and corresponding mask designs generated by ILT optimizations based on those target mask designs. Mask designs output by trained ML ILT models are accurately predictive of masks designs generated by ILT optimizations. However, in some instances, mask designs output by trained ML ILT models may not satisfy accuracy requirements across an entire layout. For example, the quality of mask designs output by a trained ML ILT model cannot exceed the quality of those mask designs from ILT optimizations on which the ML ILT model is trained. At best, ML ILT models, by themselves, can output mask designs having the same quality as those mask designs from ILT optimizations on which the ML ILT models are trained. Moreover, if a target mask design includes a feature or shape that a ML ILT model did not encounter in training of that ML ILT model, the predicted ILT mask design output by that ML ILT model may include unexpected and/or unmanufacturable features.

Aspects of the technology disclosed herein include generating training data sets using mask designs from standard cell libraries for given technology nodes. The training data set includes target mask designs and corresponding mask designs generated by ILT optimizations based on those target mask designs. The training data set can be expanded via augmentations (e.g., one or more of rotations, crops, flips, etc.) of mask designs from standard cell libraries. This expansion of the training data set can increase the coverage of ML ILT models, for example, in terms of feature types and/or shapes, which can improve generalization of predictions by the ML ILT models to various shapes and/or geometries. The training data set can include target mask designs having varying levels of density, which can reduce tendency of trained ML ILT models to overfit on a particular subset of possible mask designs. Aspects of the technology disclosed herein include generating training data sets via an automated workflow to generate target mask designs by randomly routing random nets.

Training data sets can include mask designs generated by predetermined quantities of iterations of ILT optimizations (e.g., on the order of 1500 iterations, at least 100 iterations, no more than 2000 iterations, etc.). After training (e.g., for a few hundred or thousand epochs), ML ILT models can learn translations from target mask designs to predicted ILT mask designs, with capability to generalize to unseen patterns.

According to one aspect of the technology, a method includes obtaining, by one or more processors, a target mask design for a semiconductor device to be fabricated; determining, by one or more processors based on a machine learning inverse lithography technology (ML ILT) model, a predicted ILT mask design corresponding to the target mask design; performing, by one or more processors, an ILT optimization using the predicted ILT mask design as an initialization point; and generating, by one or more processors based on completion of the ILT optimization, a mask design in order to fabricate the semiconductor device.

In an example, the method may include determining, by one or more processors, a mask pattern based on the mask design by simulating one or more lithographic processes.

Alternatively or additionally to the above, the method may include training, by one or more processors, the ML ILT model using a set of target mask designs and a set of mask designs based on the ILT optimization. The set of target mask designs may include one or more mask designs from a standard cell library. The set of target mask designs may include one or more augmented mask designs based on a standard cell library. Training the ML ILT model may include determining, by one or more processors based on the ML ILT model, another predicted ILT mask design corresponding to a given target mask design of the set of target mask designs; and determining, by one or more processors, a level of difference between the other predicted ILT mask design and a given mask design of the set of mask designs corresponding to the given target mask design. Here, the method may include determining, by one or more processors, whether the level of difference exceeds a threshold level of difference. Here, the method may include, responsive to determining that the level of difference does not exceed the threshold level of difference, determining, by one or more processors, that the ML ILT model is fully trained.

Alternatively or additionally to the above, the semiconductor device may be a component of an integrated circuit (IC) device.

Alternatively or additionally to the above, the semiconductor device may be a component of at least one of a microelectromechanical systems (MEMS) device, a photonic device or a display device.

According to another aspect of the technology, a system is provided that comprises memory configured to store at least one of a machine learning inverse lithography technology (ML ILT) model and a target mask design for a semiconductor device to be fabricated, and one or more processors operatively coupled to the memory. The one or more processors are configured to: determine, based on the ML ILT model, a predicted ILT mask design corresponding to the target mask design; perform an ILT optimization using the predicted ILT mask design as an initialization point; and generate, based on completion of the ILT optimization, a mask design in order to fabricate the semiconductor device.

In an example, the one or more processors may be further configured to simulate one or more lithographic processes using the mask design; and determine a mask pattern based on the simulation of the one or more lithographic processes.

Alternatively or additionally to the above, the memory may be further configured to store a set of target mask designs and a set of mask designs based on the ILT optimization. The one or more processors may be further configured to train the ML ILT model using the set of target mask designs and the set of mask designs. The set of target mask designs may include one or more mask designs from a standard cell library. The set of target mask designs may include one or more augmented mask designs based on a standard cell library. The one or more processors may be configured to: train the ML ILT model by being configured to determine, based on the ML ILT model, another predicted ILT mask design corresponding to a given target mask design of the set of target mask designs; and determine a level of difference between the other predicted ILT mask design and a given mask design of the set of mask designs corresponding to the given target mask design. Here, the one or more processors may be further configured to determine whether the level of difference exceeds a threshold level of difference. Here, the one or more processors may be further configured to, responsive to a determination that the level of difference does not exceed the threshold level of difference, determine that the ML ILT model is fully trained.

Alternatively or additionally to the above, the semiconductor device may be a component of an integrated circuit (IC) device.

Alternatively or additionally to the above, the semiconductor device may be a component of at least one of a microelectromechanical systems (MEMS) device, a photonic device or a display device.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1 illustrates an integrated circuit design flow in accordance with aspects of the technology.

FIG. 2 illustrates an example system that may be employed with aspects of the technology.

FIGS. 3A-J illustrate examples of target mask designs and mask designs generated by selected ILT optimizations based on those target mask designs that can be used in training ML ILT models in accordance with aspects of the technology.

FIGS. 4A-C illustrate examples of mask designs output by ML ILT models based on mask designs in accordance with aspects of the technology.

FIGS. 5A-B illustrate examples of comparisons of simulated mask patterns based on mask designs to those target mask designs in accordance with aspects of the technology.

FIGS. 6A-B illustrate examples of simulated mask patterns based on mask designs in accordance with aspects of the technology.

FIGS. 7A-B illustrate examples of simulated mask patterns based on augmented mask designs in accordance with aspects of the technology.

FIGS. 8A-L illustrate examples of comparisons of optimizations using a hybrid ILT optimization approach in accordance with aspects of the technology to selected ILT optimizations.

FIG. 9 illustrates an example method in accordance with aspects of the technology.

### DETAILED DESCRIPTION

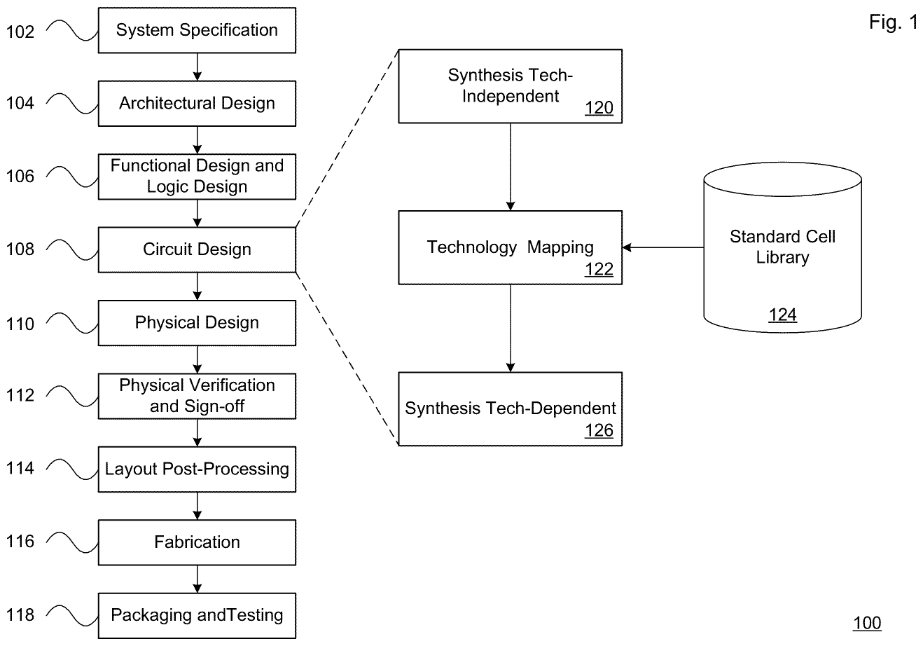

FIG. 1 illustrates an exemplary integrated circuit design flow 100 for use with aspects of the technology, including generating a circuit design and/or fabricating an integrated circuit that incorporates determining potential manufacturing defects in a mask pattern. As shown, the design flow may include preparing a system specification at block 102, such as to identify system-level requirements for the integrated circuit. The system specification is intended to capture the overall goal of the desired integrated circuit. This may include determining the device's cost, performance, general architecture, how off-chip communication will be conducted, etc. The process flow may also include performing architectural design at block 104. At this stage, the design's architecture and its layout are determined by design engineers. This can include integration of memory management, analog and/or mixed-signal components, on-device and external communication, any power constraints, choice of process technology and/or layer stacks, etc.

The process flow continues with performing functional design and logic design at block 106, and performing circuit design at block 108. Functional design may include refinement of the design's specification to achieve the functional behavior of the desired system. Logic design involves adding the design's structure to a behavioral representation of the desired design. Here, considerations include logic minimization, performance enhancement, as well as testability. This stage may consider problems associated with test vector generation, error detection and correction, and the like. By way of example, the functional design and logic design may include generating a behavioral model description (e.g., using HDL) and floor-planning. During circuit design, logic blocks are replaced by corresponding electronic circuits, which may include devices such as resistors, capacitors, and/or transistors. At this stage, circuit simulation may be performed in order to verify timing behavior and other constraints of the system. A Spice tool or other program may be used for circuit simulation.

Once the circuit design is complete, physical design may be performed at block 110 (e.g., component and wiring placement and routing), followed by physical verification and sign-off at block 112 (e.g., to obtain GDSII information with shapes to form the masks used to create the layers for fabricating the integrated circuit). During physical design, the actual layout of the integrated circuit is performed. Here, all of the components are placed and interconnected using metal interconnections. During this stage, the system may perform optimization of curvilinear interconnects, alternatively or additionally to any other layout operations. A circuit design that is able to pass testing of a circuit simulator in the circuit design stage may be found to be faulty after it has been packaged, e.g., due to geometric design rule issues. Thus, physical design rules are followed to ensure correctness during chip fabrication. Errors may include short or open circuits, open channels, or other issues may result when physical design rules are not followed. During physical verification and sign-off, the system performs any verification steps that are required before chip manufacturing. This can include design rule checking and correction, timing simulation, electromagnetic simulation, etc.

Layout post-processing occurs at block 114, then fabrication at block 116, and the packaging and testing at block 118. At block 114, the layout post-processing may include geometry processing before actual manufacturing, e.g., any dummy fill insertion, correction for optical proximity, mask optimization, etc. Fabrication comprises semiconductor manufacturing, which includes stages such as lithography patterning (masking), baking or annealing, etching, etc. Then the raw die of the chip is inserted into a package and I/O pins are connected to the package at block 118. Testing of the chip also occurs at this stage.

As shown, in the circuit design phase of block 108, the process may involve technology-independent synthesis at block 120. This step involves transferring the circuit definitions, such as register-transfer-level (RTL) descriptions, into generic data structures such as And-inverter graph (AIG), and optimizing the circuit in terms of nodes and levels. At block 122, technology mapping is performed based on information from a standard cell library 124. This step involves maps the generic optimized AIG descriptions into real, manufacturable standard cells included in the standard cell library. From this, technology-dependent synthesis is then performed at block 126. This step further optimizes the circuit defined in the gate-level netlist in terms of power, performance and area, using standard-cell-based definitions from block 122.

### Example Integrated Circuit Development System

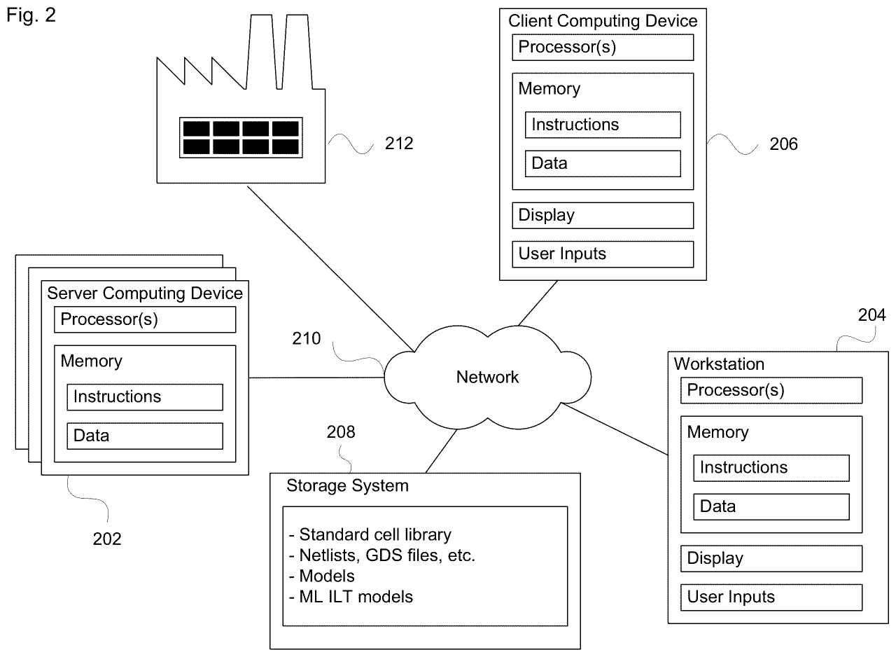

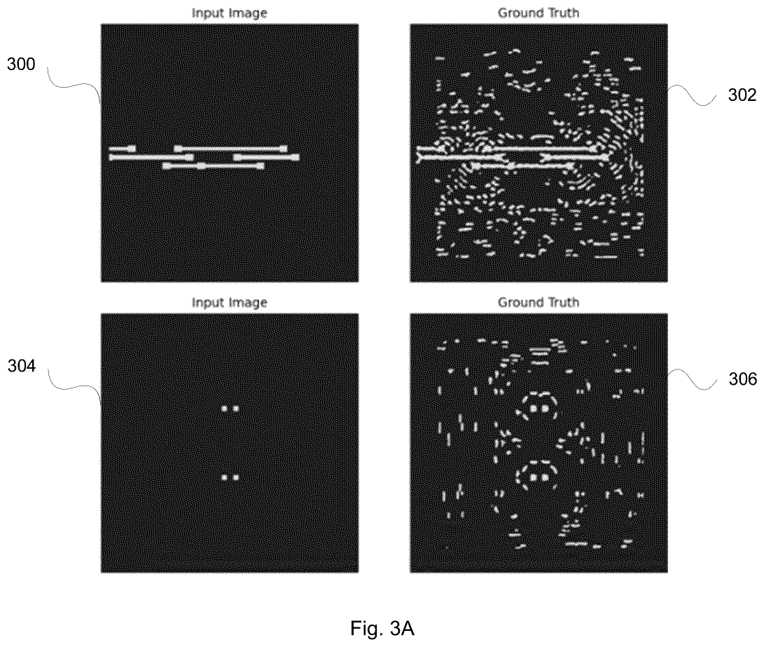

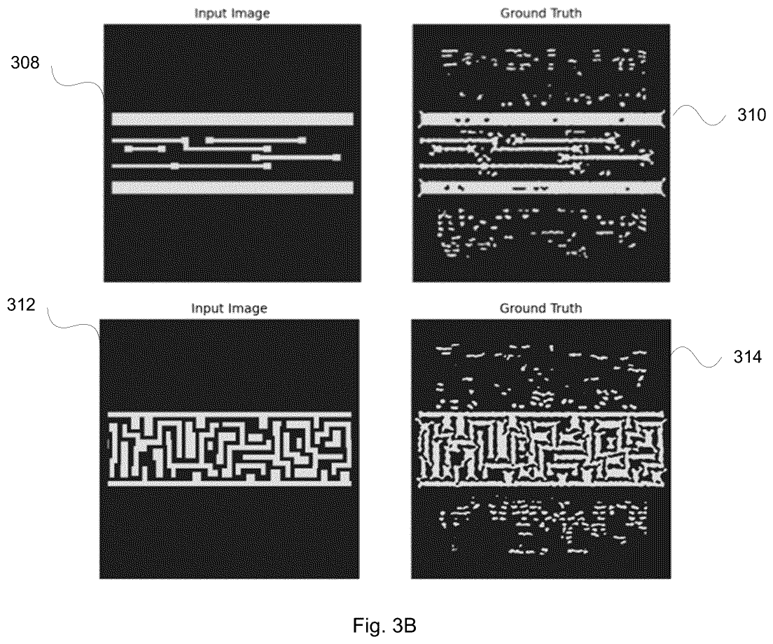

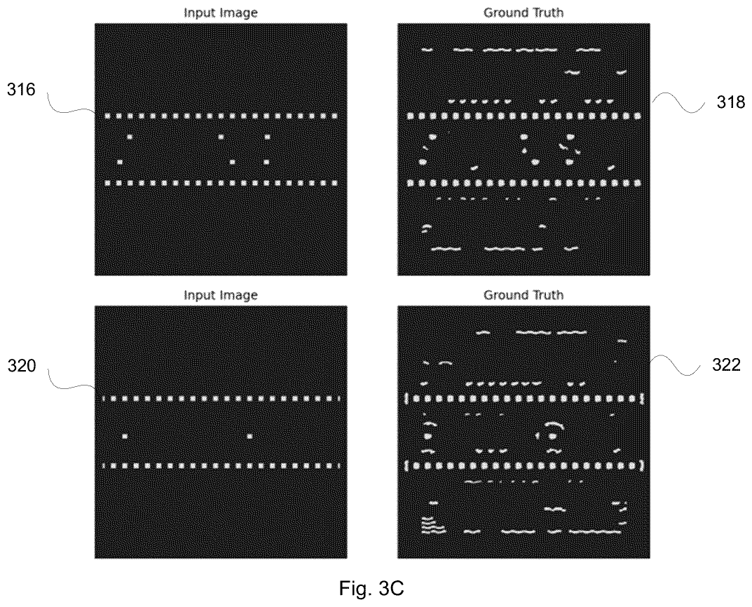

One example of a system for performing circuit design and fabrication is shown in FIG. 2. In particular, FIG. 2 is a functional diagram, of an example system 200 that includes a plurality of computing devices 202, 204, 206 and a storage system 208 connected via a network 210. System 200 may also include a fabrication facility 212 that is configured to produce integrated circuits designed according to the processes described herein. As shown in FIG. 2, each of computing devices 202, 204 and 206 may include one or more processors, memory, data and instructions.

By way of example, the one or more processors may be any conventional processors, such as commercially available central processing units (CPUs), graphical processing units (GPUs) or tensor processing unites (TPUs). Alternatively, the one or more processors may include a dedicated device such as an ASIC or other hardware-based processor. As shown in FIG. 2, the memory for each computing device stores information accessible by the one or more processors, including instructions and data that may be executed or otherwise used by the processor(s). The memory may be of any type capable of storing information accessible by the processor, including a computing device or computer-readable medium, or other medium that stores data that may be read with the aid of an electronic device, such as a hard-drive, memory card, ROM, RAM, DVD or other optical disks, as well as other write-capable and read-only memories. Systems and methods may include different combinations of the foregoing, whereby different portions of the instructions and data are stored on different types of media.

Moreover, reference to “one or more processors” herein includes situations where a set of processors may be configured to perform one or more operations. Any combination of such a set of processors may perform individual operations or a group of operations. This may include two or more CPUs, GPUs or TPUs (or other hardware-based processors) or any combination thereof. It may also include situations where the processors have multiple processing cores. Therefore, reference to “one or more processors” does not require that all processors (or cores) in the set must each perform all of the operations. Rather, unless expressly stated, any one of the one or more processors (or cores) may perform different operations when a set of operations is indicated, and different processors (or cores) may perform specific operations, either sequentially or in parallel.

The instructions may be any set of instructions to be executed directly (such as machine code) or indirectly (such as scripts) by the processor. For example, the instructions may be stored as computing device code on the computing device-readable medium. In that regard, the terms “instructions” and “programs” may be used interchangeably herein. The instructions may be stored in object code format for direct processing by the processor, or in any other computing device language including scripts or collections of independent source code modules that are interpreted on demand or compiled in advance.

The data may be retrieved, stored or modified by processor in accordance with the instructions. For instance, although the claimed subject matter is not limited by any particular data structure, the data may be stored in computing device registers, in a relational database as a table having a plurality of different fields and records, XML documents or flat files, HDL information, GDSII information, etc. The data may also be formatted in any computing device-readable format.

The computing devices may include all of the components normally used in connection with a computing device such as the processor and memory described above as well as a user interface having one or more user inputs (e.g., one or more of a button, mouse, keyboard, touch screen, gesture input and/or microphone), various electronic displays (e.g., a monitor having a screen or any other electrical device that is operable to display information), and speakers. The computing devices may also include a communication system having one or more wired or wireless connections to facilitate communication with other computing devices of system 200 and/or the fabrication facility 212.

The various computing devices may communicate directly or indirectly via one or more networks, such as network 210. The network 210 and any intervening nodes may include various configurations and protocols including short range communication protocols such as Bluetooth™, Bluetooth LE™, the Internet, World Wide Web, intranets, virtual private networks, wide area networks, local networks, private networks using communication protocols proprietary to one or more companies, Ethernet, WiFi and HTTP, and various combinations of the foregoing. Such communication may be facilitated by any device capable of transmitting data to and from other computing devices, such as modems and wireless interfaces.

In one example, computing device 202 may include one or more server computing devices having a plurality of computing devices, e.g., a load balanced server farm or cloud computing architecture, which exchange information with different nodes of a network for the purpose of receiving, processing, and transmitting the data to and from other computing devices. For instance, computing device 202 may include one or more server computing devices that are capable of communicating with computing devices 204, 206 and the fabrication facility 212 via the network 210. In some examples, client computing device 204 may be an engineering workstation used by a developer to perform circuit design and/or other processes for integrated circuit design and fabrication. Client computing device 206 may also be used by a developer, for instance to prepare system requirements for the integrated circuit or manage the manufacturing process with the fabrication facility 212.

Storage system 208 can be of any type of computerized storage capable of storing information accessible by the server computing devices 202, 204 and/or 206, such as a hard-drive, memory card, ROM, RAM, DVD, CD-ROM, flash drive and/or tape drive. In addition, storage system 208 may include a distributed storage system where data is stored on a plurality of different storage devices which may be physically located at the same or different geographic locations. Storage system 208 may be connected to the computing devices via the network 210 as shown in FIG. 2, and/or may be directly connected to or incorporated into any of the computing devices.

Storage system 208 may store various types of information. For instance, the storage system 208 may store training data sets for ML ILT models, one or more trained ML ILT models, models of lithography processing steps, and/or other processes as well as instructions for selected conventional ILT optimizations and other processes described herein.

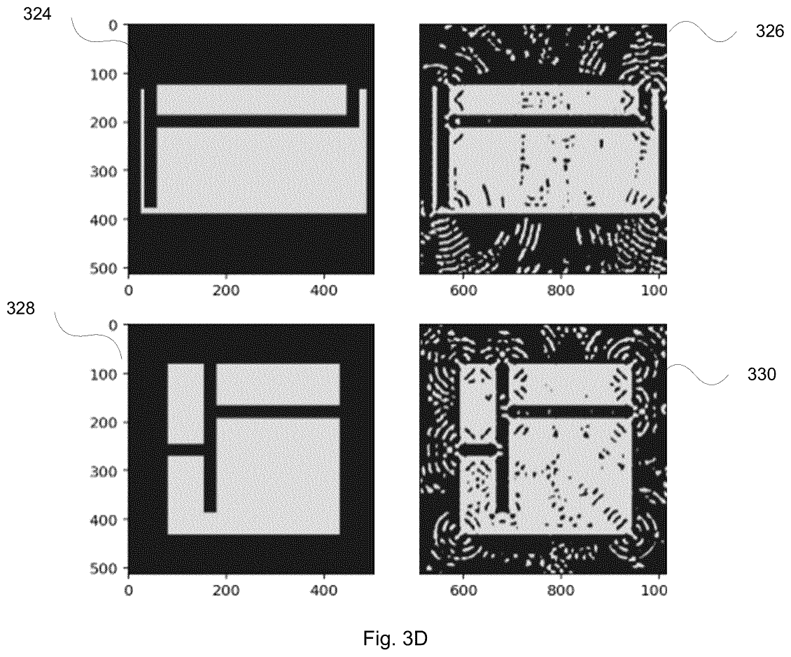

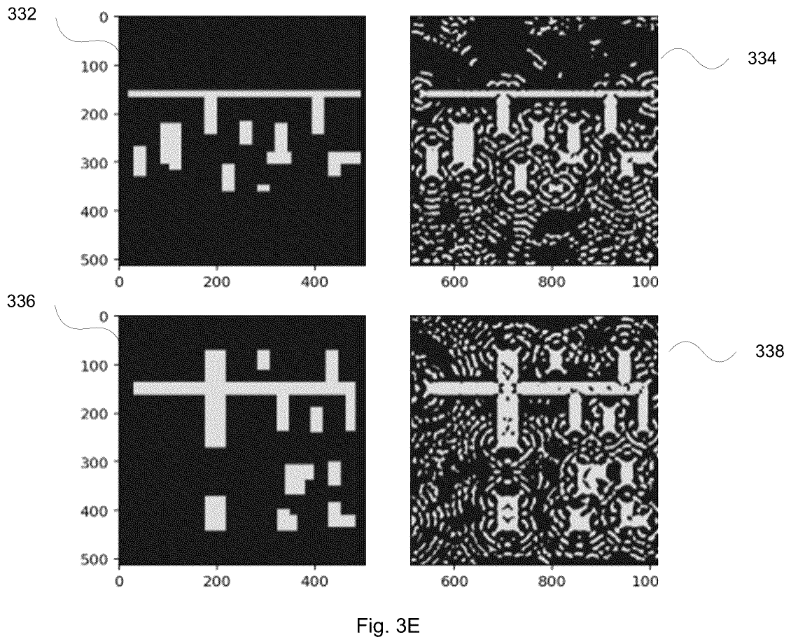

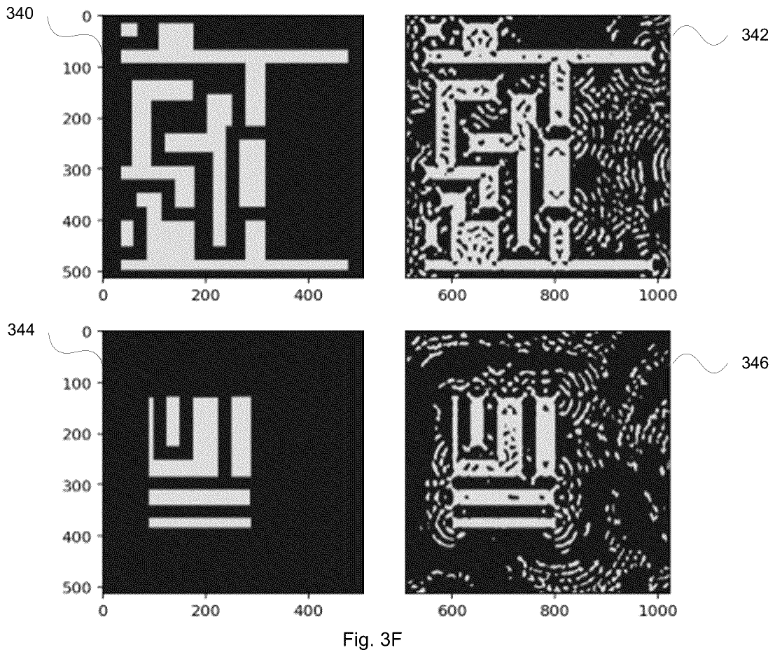

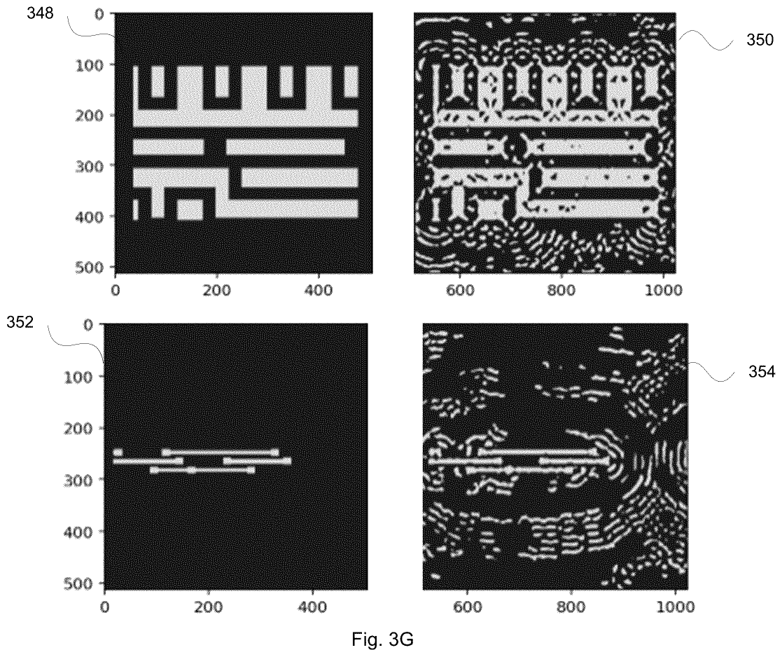

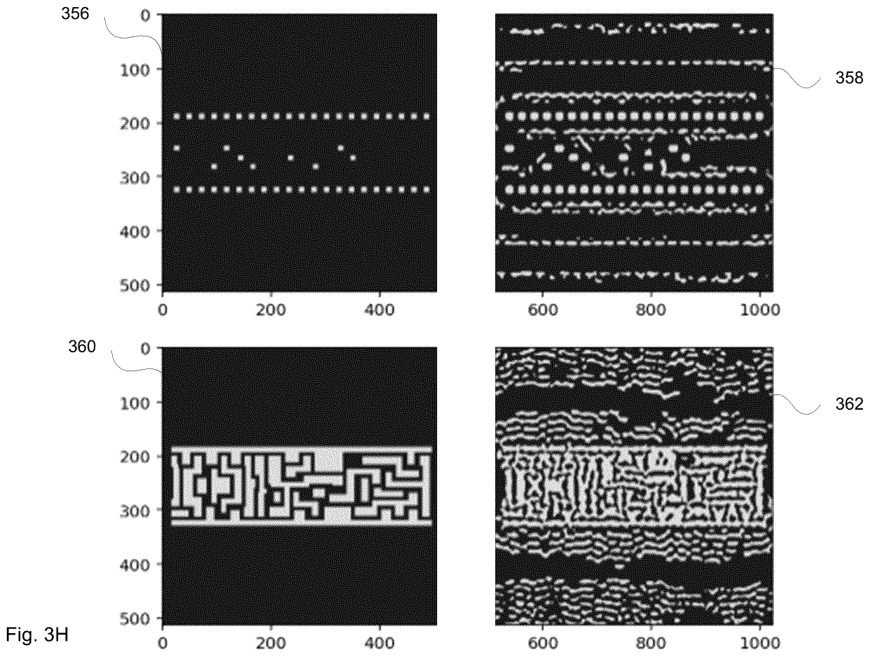

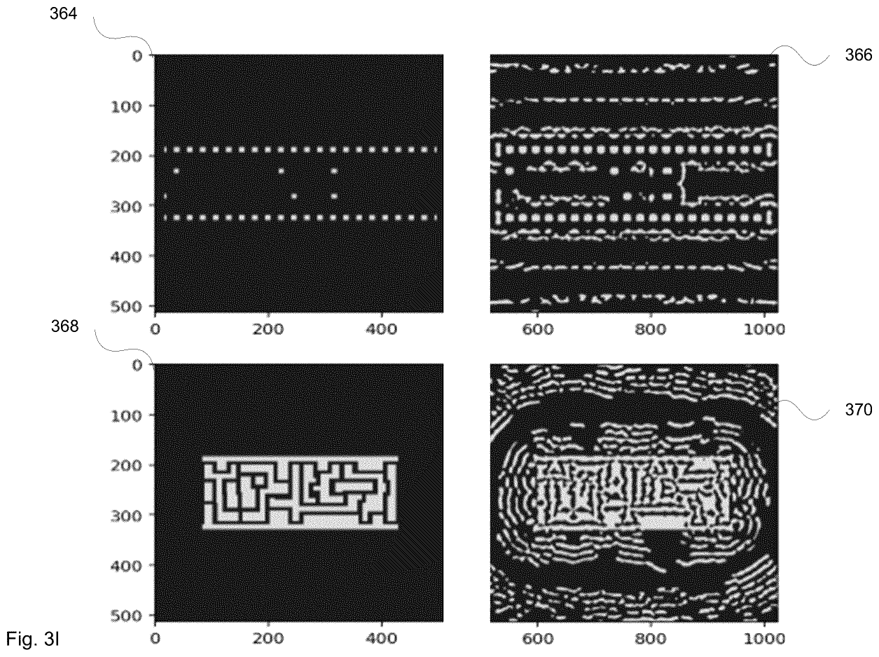

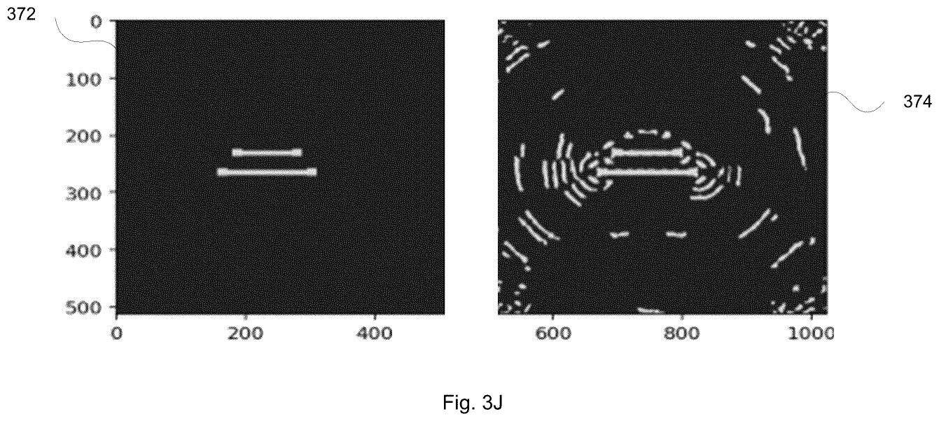

FIGS. 3A-F illustrate examples of target mask designs and mask designs generated by selected ILT optimizations based on those target mask designs that can be used in training ML ILT models in accordance with aspects of the technology. As used herein, “target mask design” refers to an intended mask pattern to be fabricated. A mask design other a target mask design, such as one generated by ILT optimizations, may be different than the target mask design but provides the intended mask pattern. A goal of training a ML ILT model is to have that ML ILT model predict, for a given target mask design, the mask design that a selected ILT optimization process would generate for that target mask design with at least a particular level of accuracy. By way of example, if the target mask design 300 is input to a trained ML ILT model, then, ideally, the trained ML ILT model will output the mask design 302, or, less ideally, a mask design similar to the mask design 302 with at least a particular level of accuracy. This applies to all pairs of a target mask design and corresponding mask design generated by ILT optimization illustrated by FIGS. 3A-J.

FIG. 3A illustrates mask design 302 generated by ILT optimization of target mask design 300, and mask design 306 generated by ILT optimization of target mask design 304. FIG. 3B illustrates mask design 310 generated by ILT optimization of target mask design 308, and mask design 314 generated by ILT optimization of target mask design 312. FIG. 3C illustrates mask design 318 generated by ILT optimization of target mask design 314, and mask design 322 generated by ILT optimization of target mask design 320. FIG. 3D illustrates mask design 326 generated by ILT optimization of target mask design 324, and mask design 330 generated by ILT optimization of target mask design 328. FIG. 3E illustrates mask design 334 generated by ILT optimization of target mask design 332, and mask design 338 generated by ILT optimization of target mask design 336. FIG. 3F illustrates mask design 342 generated by ILT optimization of target mask design 340, and mask design 346 generated by ILT optimization of target mask design 344. FIG. 3G illustrates mask design 350 generated by ILT optimization of target mask design 348, and mask design 354 generated by ILT optimization of target mask design 352. FIG. 3H illustrates mask design 358 generated by ILT optimization of target mask design 356, and mask design 362 generated by ILT optimization of target mask design 360. FIG. 3I illustrates mask design 366 generated by ILT optimization of target mask design 364, and mask design 370 generated by ILT optimization of target mask design 368. FIG. 3J illustrates mask design 374 generated by ILT optimization of target mask design 372.

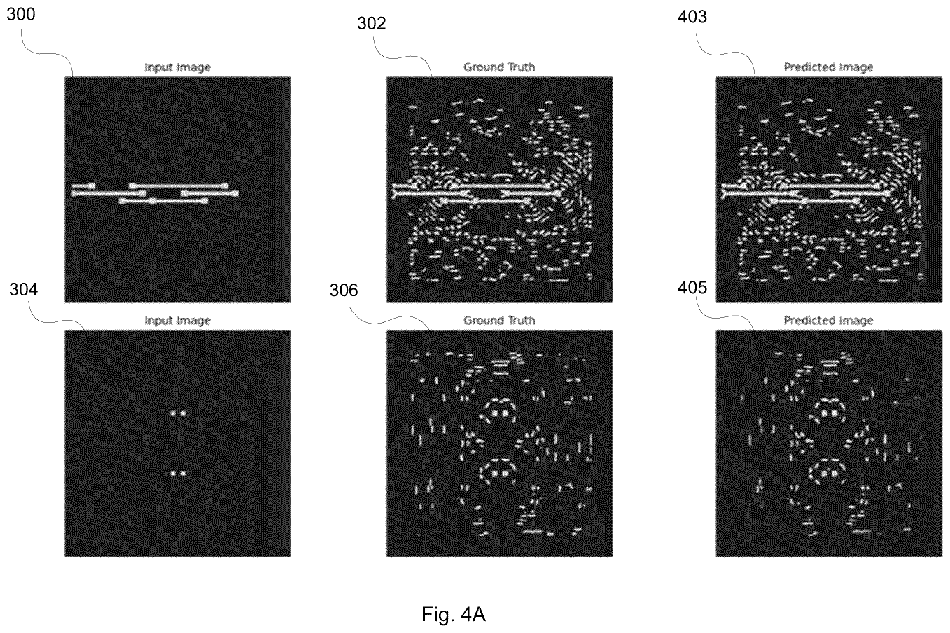

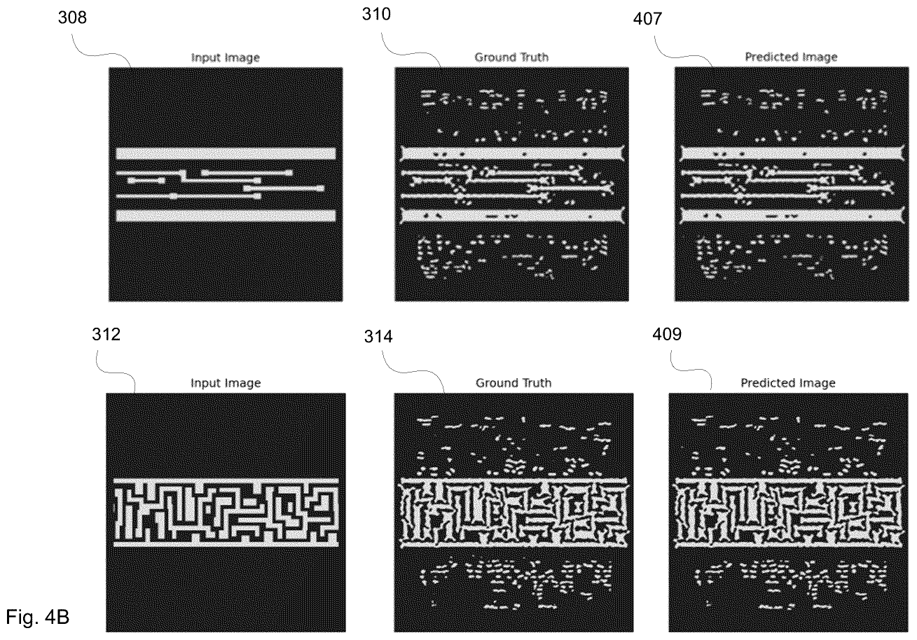

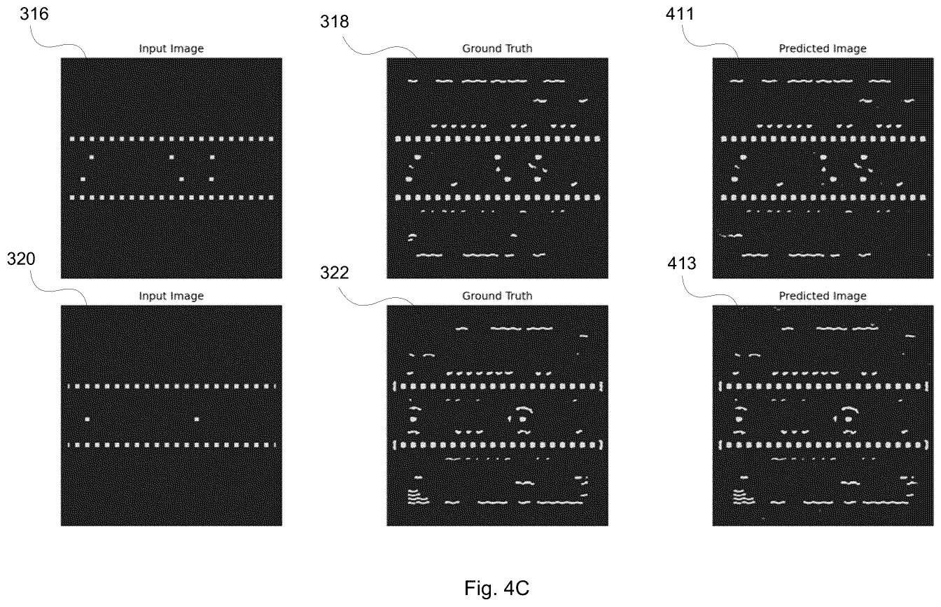

FIGS. 4A-C illustrate examples of predicted ILT mask designs in accordance with aspects of the technology. By way of example, predicted ILT mask design 403 is output by a ML ILT model when the target mask design 300 is input to that ML ILT model outputs. As demonstrated by comparing the mask design 302 generated by a selected ILT optimization to the predicted ILT mask design 403, the predicted ILT mask design 403 is very similar to the mask design 302. The same is true for each pair of mask designs generated by an ILT optimization and predicted ILT mask design illustrated by FIGS. 4A-C. A ML ILT model can be trained until a predicted ILT mask design output by that ML ILT model for a given target mask design has at least a threshold level of accuracy relative to a mask design generated by an ILT optimization for that target mask design.

FIG. 4A illustrates, for the target mask design 300, the mask design 302 generated by an ILT optimization of the target mask design 300 and the predicted ILT mask design 403. FIG. 4A illustrates, for the target mask design 304, the mask design 306 generated by an ILT optimization of the target mask design 304 and predicted ILT mask design 405.

FIG. 4B illustrates, for the target mask design 308, the mask design 310 generated by an ILT optimization of the target mask design 308 and predicted ILT mask design 407. FIG. 4B illustrates, for the target mask design 312, the mask design 314 generated by an ILT optimization of the target mask design 312 and the predicted ILT mask design 409.

FIG. 4C illustrates, for the target mask design 316, the mask design 318 generated by an ILT optimization of the target mask design 316 and predicted ILT mask design 411. FIG. 4C illustrates, for the target mask design 320, the mask design 322 generated by an ILT optimization of the target mask design 320 and predicted ILT mask design 413.

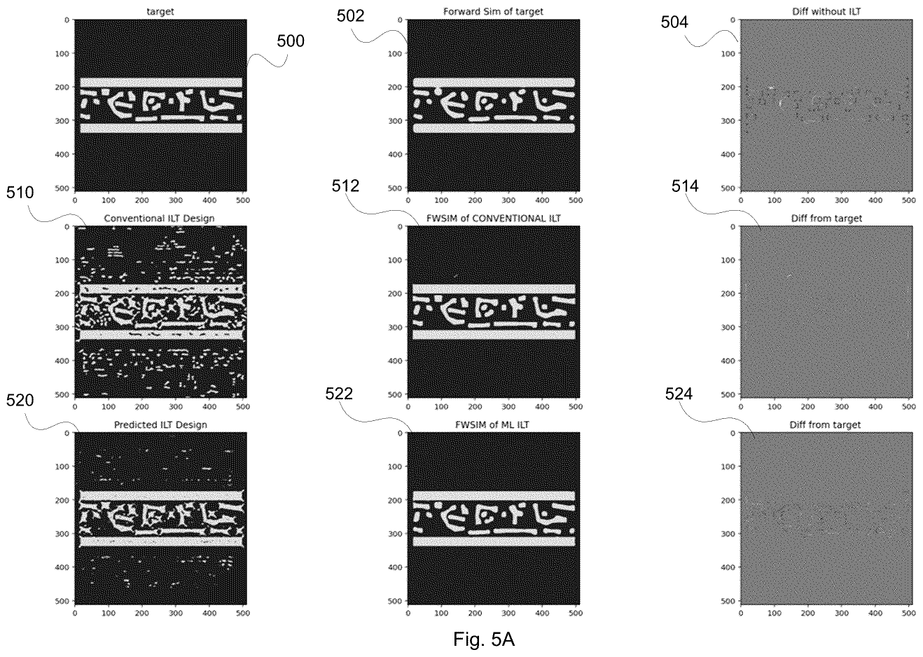

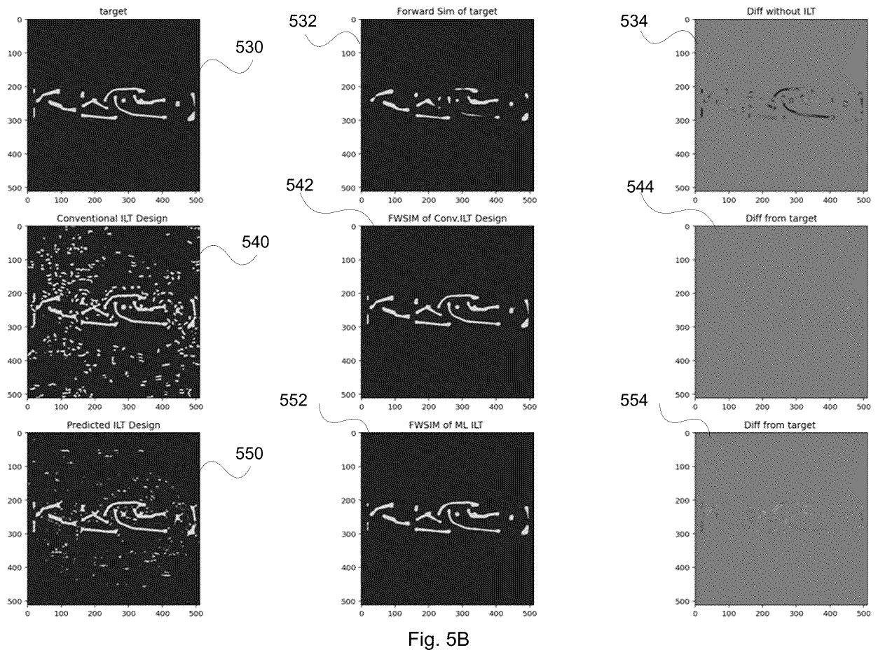

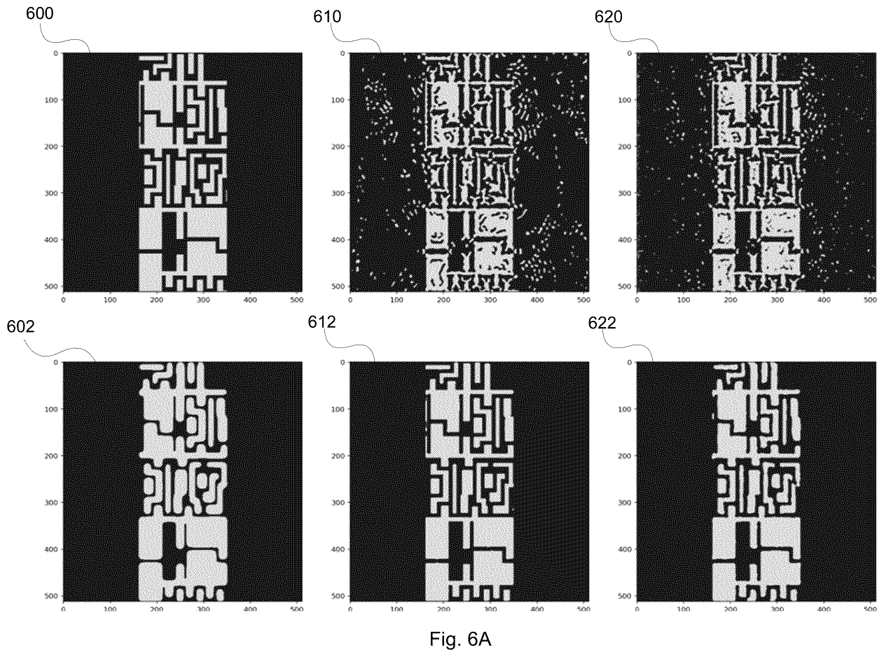

FIGS. 5A-B illustrate examples of comparisons of simulated mask patterns based on mask designs to target mask designs in accordance with aspects of the technology. These mask patterns are results from simulating one or more lithography processes (e.g., mask writing) using a mask design.

By way of example, FIG. 5A illustrates target mask design 500 (not optimized), mask design 510 generated by an ILT optimization of the target mask design 500, and predicted ILT mask design 520 output by a trained ML ILT model based on the target mask design 500. The mask design 510 is generated by the ILT optimization after a runtime of approximately thirty minutes. In contrast, the predicted ILT mask design 520 is output by the ML ILT model after a runtime of a few milliseconds.

Mask pattern 502 is a result of simulating lithography processes using the target mask design 500. Mask pattern 512 is a result of simulating lithography processes using the mask design 510. Mask pattern 522 is a result of simulating lithography processes using the predicted ILT mask design 520.

Unlike the mask pattern 502, the mask pattern 512, resulting from the ILT optimization, includes sharp features (e.g., sharp corners) as in the target design 500. The mask pattern 522 also includes sharp features as in the target design 500. Although, there are differences between the mask design 510 generated by an ILT optimization and the predicted ILT mask design 520, the mask pattern 522 closely resembles the target mask design 500 and the mask pattern 512. Additionally, like the mask pattern 512, the mask pattern 522 does not include the defects (e.g., bridging defects) of the mask pattern 502.

FIG. 5A illustrates a comparison 504 of the mask pattern 502 to the target mask design 500, a comparison 514 of the mask pattern 512 to the target mask design 500, and a comparison 524 of the mask pattern 522 to the target mask design 500. Although the mask pattern 522 includes more differences relative to the target mask design 500 than the mask pattern 512, the mask pattern 522 still closely resembles the mask pattern 512 without the defects of the mask pattern 502. Moreover, the mask pattern 522 has fewer differences than the mask pattern 502 based on the unoptimized target mask design 500.

By way of example, FIG. 5B illustrates target mask design 530 (not optimized), mask design 540 generated by an ILT optimization of the target mask design 530, and predicted ILT mask design 550 output by a trained ML ILT model based on the target mask design 530. The mask design 540 is generated by the ILT optimization after a runtime of approximately thirty minutes. In contrast, the predicted ILT mask design 550 is output by the ML ILT model after a runtime of a few milliseconds.

Mask pattern 532 is a result of simulating lithography processes using the target mask design 530. Mask pattern 542 is a result of simulating lithography processes using the mask design 540. Mask pattern 552 is a result of simulating lithography processes using the predicted ILT mask design 550.

Although there are differences between the mask design 540 generated by an ILT optimization and the predicted ILT mask design 550, the mask pattern 552 closely resembles the target mask design 530, and the mask pattern 542. Additionally, like the mask pattern 542, the mask pattern 552 does not include the defects of the mask pattern 532.

FIG. 5B illustrates a comparison 534 of the mask pattern 532 to the target mask design 530, a comparison 544 of the mask pattern 542 to the target mask design 530, and a comparison 554 of the mask pattern 552 to the target mask design 530. Although the mask pattern 532 includes more differences relative to the target mask design 530 than the mask pattern 542, the mask pattern 552 still closely resembles the mask pattern 542. Moreover, the mask pattern 552 has significantly fewer differences than the mask pattern 532 based on the unoptimized target mask design 530.

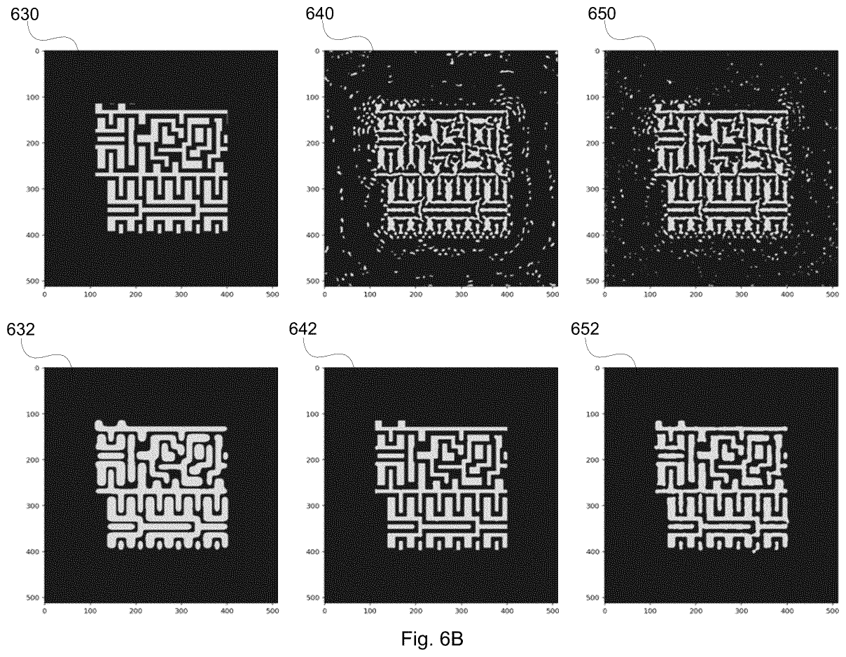

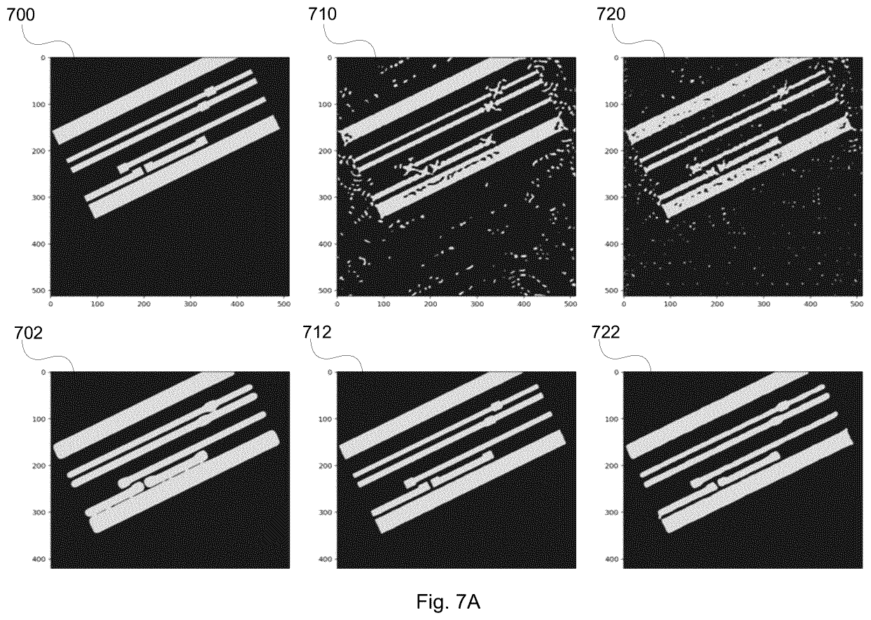

FIGS. 6A-B illustrate examples of simulated mask patterns based on mask designs in accordance with aspects of the technology. These mask patterns are results from simulating one or more lithography processes (e.g., mask writing) using a mask design.

By way of example, FIG. 6A illustrates target mask design 600 (not optimized), mask design 610 generated by an ILT optimization of the target mask design 600, and predicted ILT mask design 620 output by a trained ML ILT model based on the target mask design 600. Mask pattern 602 is a result of simulating lithography processes using the target mask design 600. Mask pattern 612 is a result of simulating lithography processes using the mask design 610. Mask pattern 622 is a result of simulating lithography processes using the predicted ILT mask design 620. Although there are differences between the mask design 610 generated by an ILT optimization and the predicted ILT mask design 620, the mask pattern 622 closely resembles the target mask design 600 and the mask pattern 612.

By way of example, FIG. 6B illustrates target mask design 630 (not optimized), mask design 640 generated by an ILT optimization of the target mask design 630, and predicted ILT mask design 650 output by a trained ML ILT model based on the target mask design 630. Mask pattern 632 is a result of simulating lithography processes using the target mask design 630. Mask pattern 642 is a result of simulating lithography processes using the mask design 640. Mask pattern 652 is a result of simulating lithography processes using the predicted ILT mask design 650. Although there are differences between the mask design 640 generated by a selected ILT optimization and the predicted ILT mask design 650, the mask pattern 652 closely resembles the target mask design 630 and the mask pattern 642.

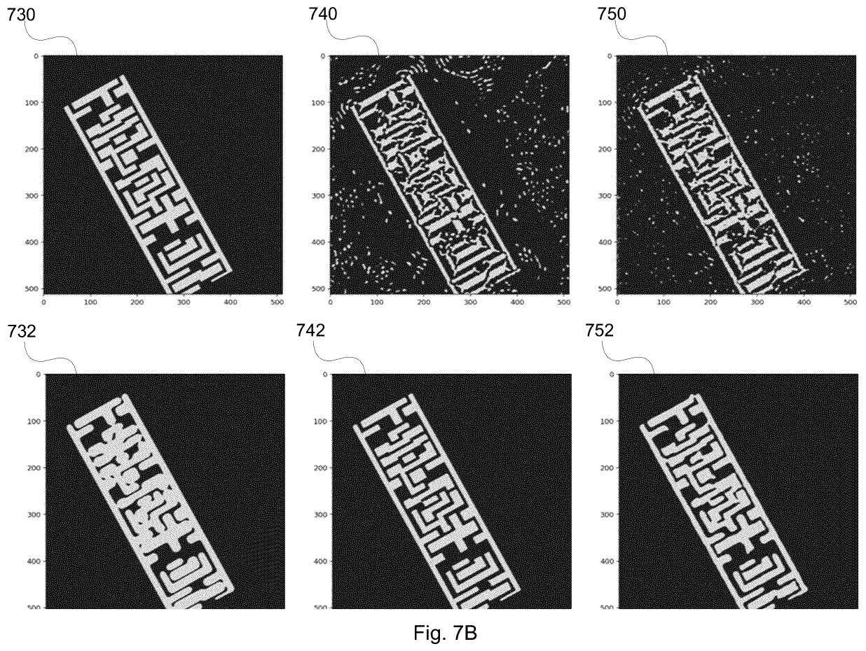

FIGS. 7A-B illustrate examples of simulated mask patterns based on augmented mask designs in accordance with aspects of the technology. These mask patterns are results from simulating one or more lithography processes using a mask design.

By way of example, FIG. 7A illustrates augmented target mask design 700 (not optimized), mask design 710 generated by a selected ILT optimization of the target mask design 700, and predicted ILT mask design 720 output by a ML ILT model based on the target mask design 700. The target mask design 700 is augmented, relative to a corresponding mask design from a standard cell library, in that the corresponding mask design from the standard cell library is rotated and cropped in this example.

Mask pattern 702 is a result of simulating lithography processes using the target mask design 700. Mask pattern 712 is a result of simulating lithography processes using the mask design 710. Mask pattern 722 is a result of simulating lithography processes using the predicted ILT mask design 720. Although there are differences between the mask design 710 generated by a selected ILT optimization and the predicted ILT mask design 720, the mask pattern 722 closely resembles the target mask design 700 and the mask pattern 712.

By way of example, FIG. 7B illustrates target mask design 730 (not optimized), mask design 740 generated by a selected ILT optimization of the target mask design 730, and predicted ILT mask design 750 output by a ML ILT model based on the target mask design 730. The target mask design 730 is augmented, relative to a corresponding mask design from a standard cell library, in that the corresponding mask design from the standard cell library is rotated and cropped.

Mask pattern 732 is a result of simulating lithography processes using the target mask design 730. Mask pattern 742 is a result of simulating lithography processes using the mask design 740. Mask pattern 752 is a result of simulating lithography processes using the predicted ILT mask design 750. Although there are differences between the mask design 740 generated by an ILT optimization and the predicted ILT mask design 750, the mask pattern 752 closely resembles the mask pattern 742.

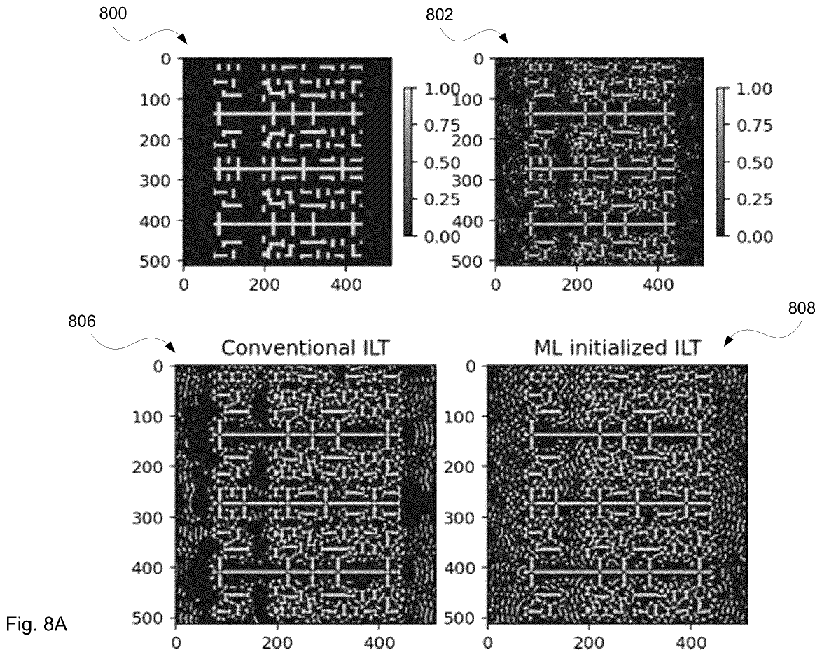

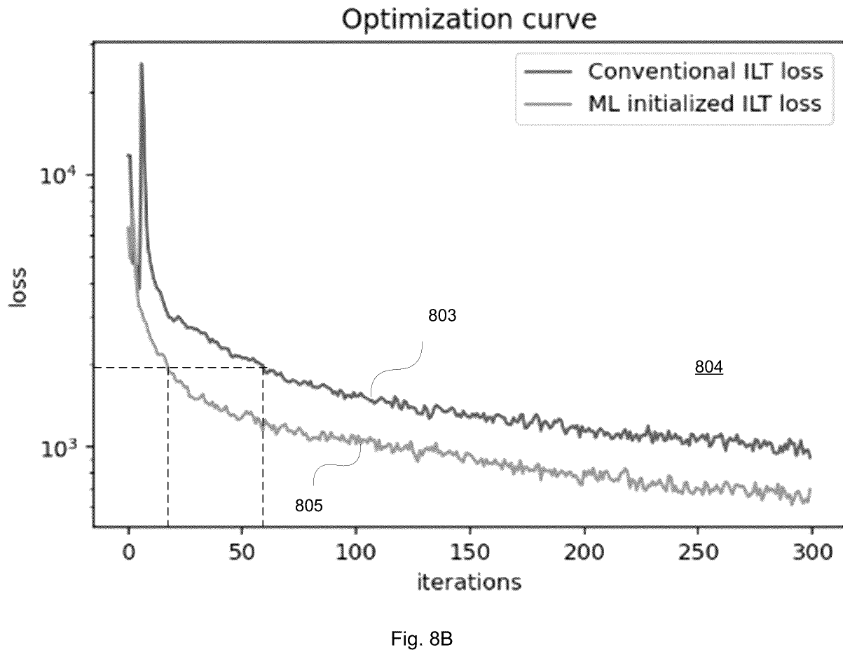

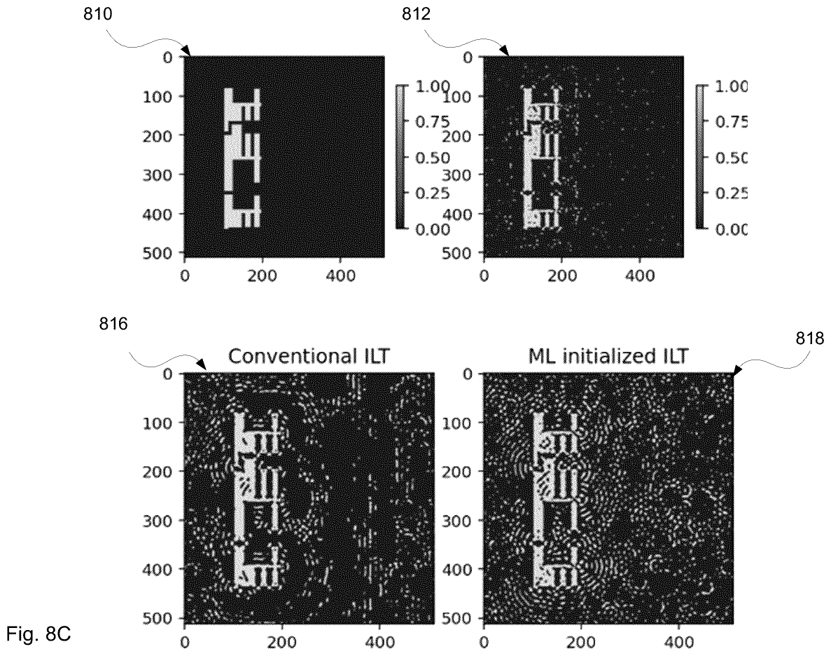

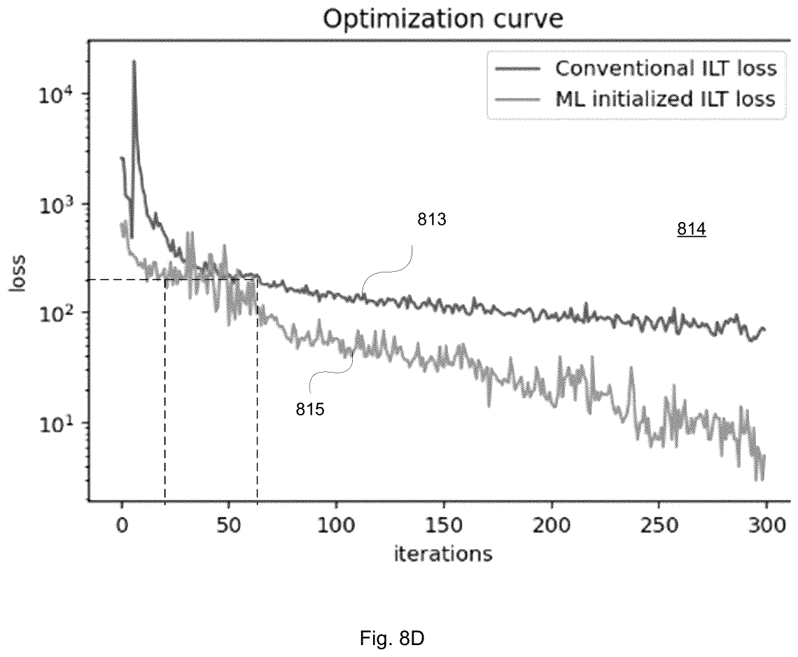

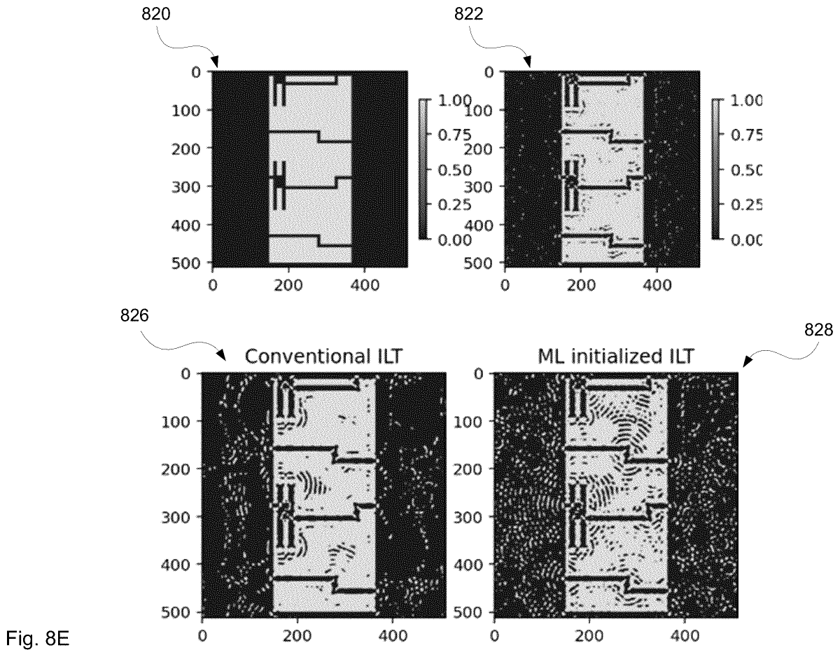

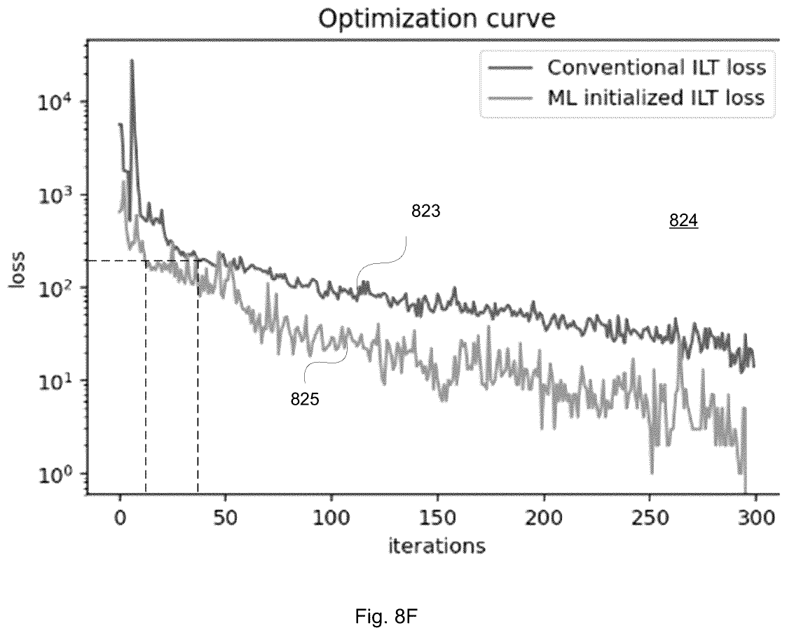

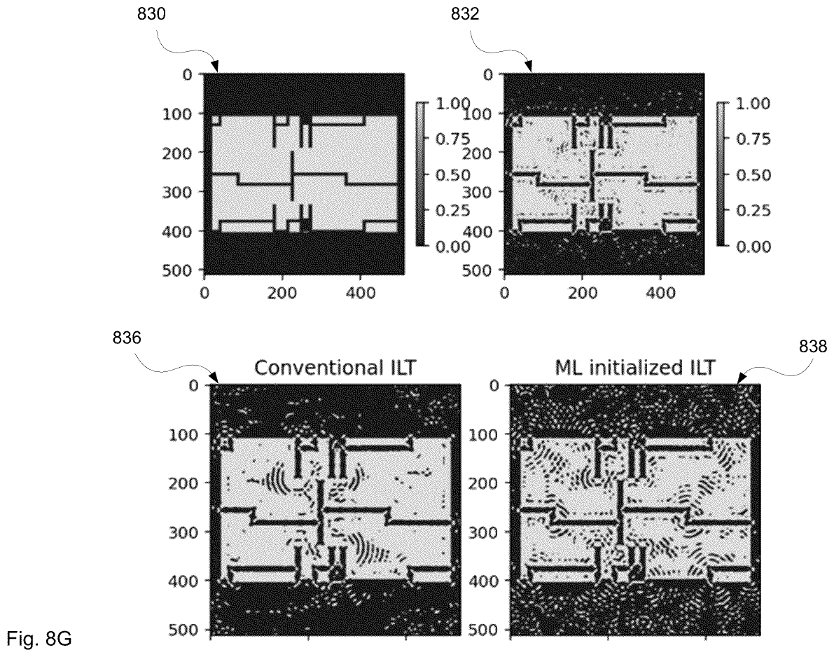

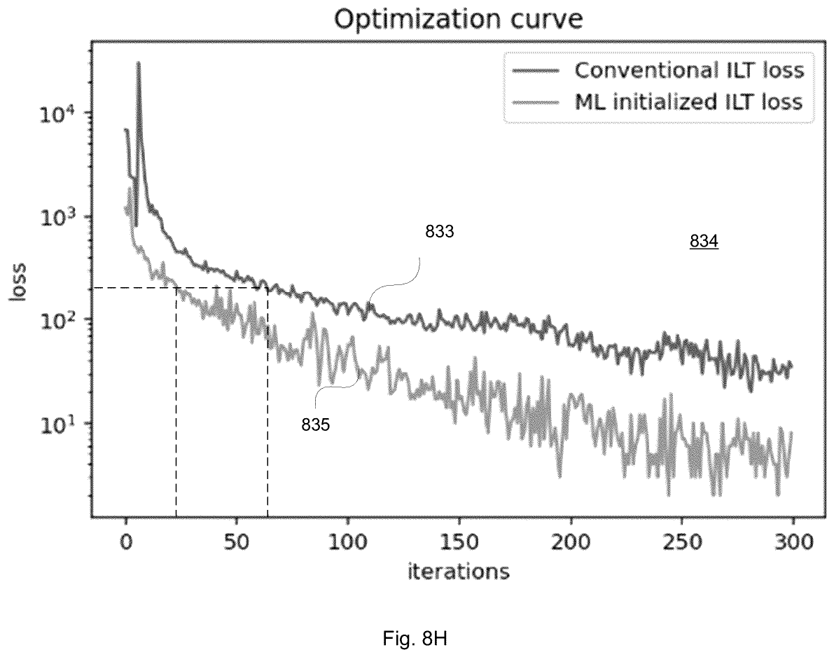

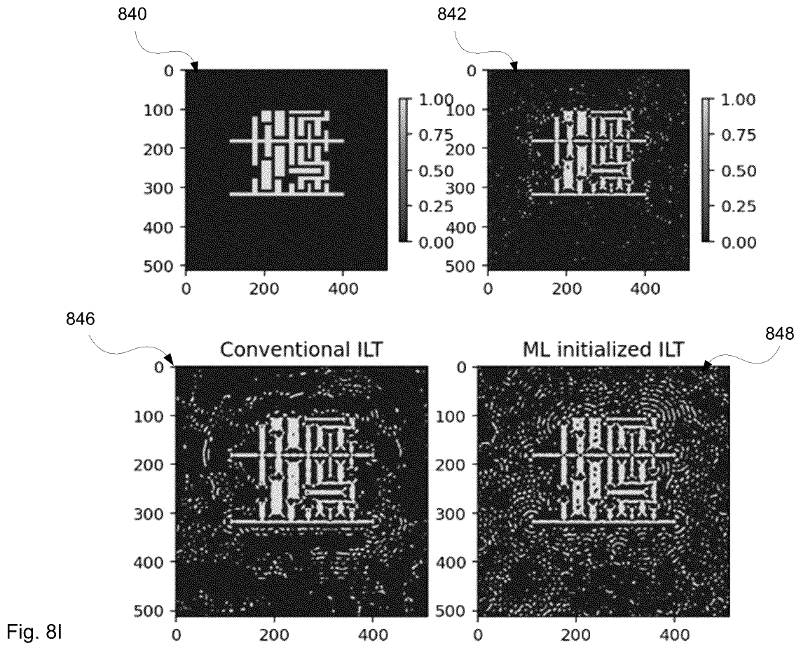

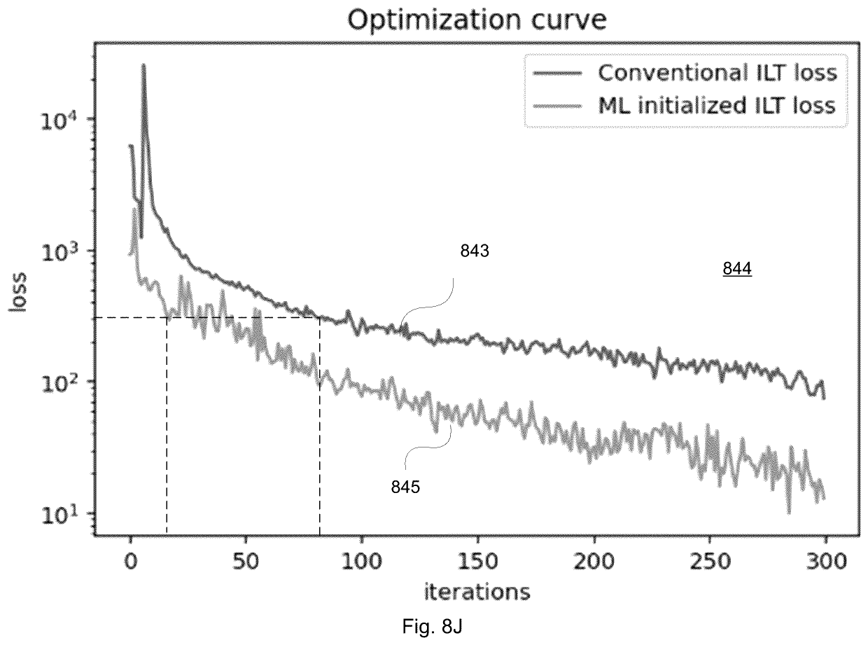

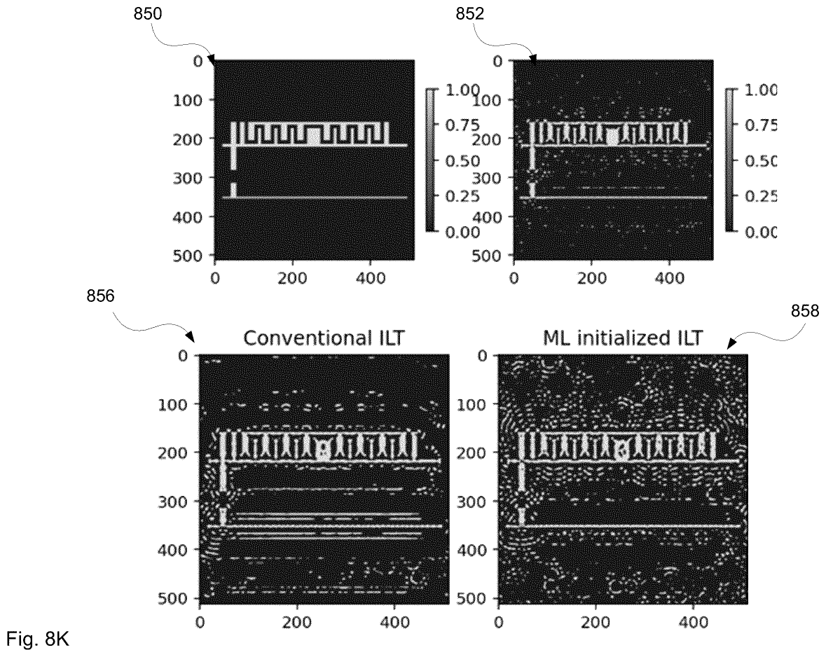

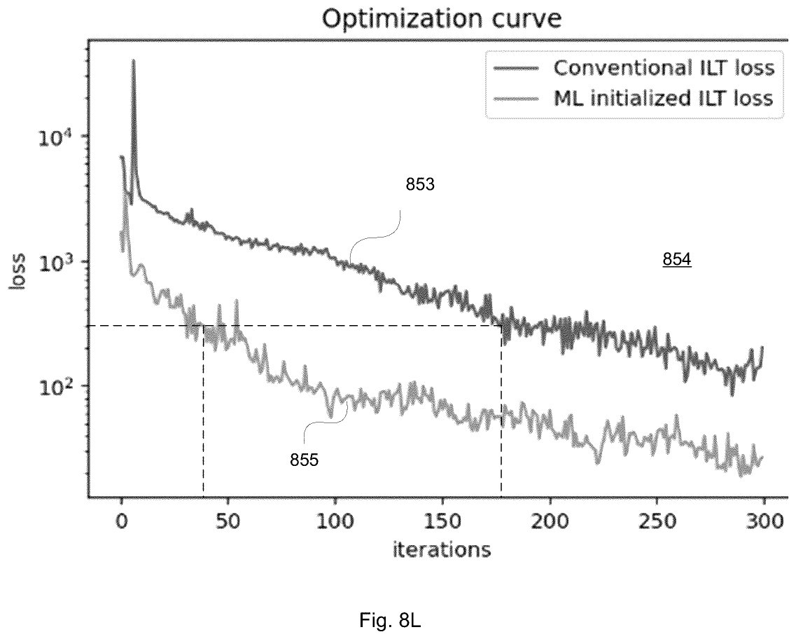

FIGS. 8A-L illustrate examples of comparisons of optimizations using a hybrid ILT optimization approach in accordance with aspects of the technology to selected ILT optimizations. FIG. 8A illustrates a target mask design 800 and a predicted ILT mask design 802 output by a ML ILT model based on the target mask design 800. FIG. 8A illustrates a mask design 806 generated by a selected ILT optimization of the target mask design 800.

FIG. 8A illustrates a mask design 808 generated by a hybrid ILT optimization approach disclosed herein. The mask design 808 is the result of a selected ILT optimization initialized with the predicted ILT mask design 802. In contrast, the mask design 806 is the result of a selected ILT optimization initialized with the target mask design 800.

FIG. 8B illustrates a graph 804 representing loss relative to the target mask design 800 achieved by an optimization as more iterations of that optimization are performed. The line 803 corresponds to the selected ILT optimization initialized with the target mask design 800. The line 805 corresponds to the hybrid ILT optimization approach, which includes the selected ILT optimization initialized with the predicted ILT mask design 802. The graph 804 shows that the hybrid ILT optimization approach provides a sustained advantage over only utilizing the selected ILT optimization. That is, the hybrid ILT optimization approach provides lesser loss values than the selected ILT optimization, even as more iterations are performed.

Moreover, the graph 804 shows that the hybrid ILT optimization approach achieves a given loss value significantly quicker than the selected ILT optimization by itself. By way of example, the selected ILT optimization achieves a loss value of approximately 2,000 after approximately 60 iterations of the selected ILT optimization initialized with the target mask design 800 (see the dashed lines). In contrast, the hybrid ILT optimization approach achieves a loss value of approximately 2,000 after only approximately 20 iterations of the selected ILT optimization initialized with the predicted ILT mask design 802. Thus, the hybrid ILT optimization approach provides the same loss value but in about a third of the time.

The hybrid ILT optimization approach provides this advantage because using the predicted ILT mask design 802 to initialize the selected ILT optimization, instead of the target mask design 800, starts the selected ILT optimization with a mask design that, in effect, has the benefit of some optimization, by virtue of the ML ILT model, already been performed on the target mask design 800, but without actually performing the selected ILT optimization on the target mask design 800. Thus, the prediction of an ILT mask design by the ML ILT model effectively replaces iterations of the selected ILT optimization that would be performed if the selected ILT optimization were initialized with the target mask design 800. As described herein, the ML ILT model effectively replaces these iterations of the selected ILT optimization in a fraction of the time it would take to perform these iterations (e.g., milliseconds) with greatly reduced computational costs.

FIG. 8C illustrates a target mask design 810 and a predicted ILT mask design 812 output by a ML ILT model based on the target mask design 810. FIG. 8C illustrates a mask design 816 generated by a selected ILT optimization of the target mask design 810. FIG. 8C illustrates a mask design 818 generated by a hybrid ILT optimization approach disclosed herein. The mask design 818 is the result of a selected ILT optimization initialized with the predicted ILT mask design 812. In contrast, the mask design 816 is the result of a selected ILT optimization initialized with the target mask design 810.

FIG. 8D illustrates a graph 814 representing loss achieved by an optimization as more iterations of that optimization are performed. The line 813 corresponds to the selected ILT optimization initialized with the target mask design 810. The line 815 corresponds to the hybrid ILT optimization approach, which includes the selected ILT optimization initialized with the predicted ILT mask design 812. The graph 814 shows that the hybrid ILT optimization approach provides a sustained advantage over the selected ILT optimization by itself. That is, the hybrid ILT optimization approach provides lesser loss values than the selected ILT optimization, even as more iterations are performed.

Moreover, the graph 804 shows that the hybrid ILT optimization approach achieves a given loss value significantly quicker than the selected ILT optimization. By way of example, the selected ILT optimization achieves a loss value of approximately 200 after approximately 60 iterations of the selected ILT optimization initialized with the target mask design 800 (see the dashed lines). In contrast, the hybrid ILT optimization approach achieves a loss value of approximately 200 after only approximately 20 iterations of the selected ILT optimization initialized with the predicted ILT mask design 812. Thus, the hybrid ILT optimization approach provides the same loss value but in about a third of the time.

The hybrid ILT optimization approach provides this advantage because using the predicted ILT mask design 812 to initialize the selected ILT optimization, instead of the target mask design 810, starts the selected ILT optimization with a mask design that, in effect, has the benefit of some optimization, by virtue of the ML ILT model, already been performed on the target mask design 810, but without actually performing the selected ILT optimization on the target mask design 810. Thus, the prediction of an ILT mask design by the ML ILT model effectively replaces many iterations of the selected ILT optimization that would be performed if the selected ILT optimization were initialized with the target mask design 800.

FIG. 8E illustrates a target mask design 820 and a predicted ILT mask design 822 output by a ML ILT model based on the target mask design 820. FIG. 8E illustrates a mask design 826 generated by a selected ILT optimization of the target mask design 820. FIG. 8E illustrates a mask design 828 generated by a hybrid ILT optimization approach disclosed herein. The mask design 828 is the result of a selected ILT optimization initialized with the predicted ILT mask design 822. In contrast, the mask design 826 is the result of a selected ILT optimization initialized with the target mask design 820.

FIG. 8F illustrates a graph 824 representing loss achieved by an optimization as more iterations of that optimization are performed. The line 823 corresponds to the selected ILT optimization initialized with the target mask design 820. The line 825 corresponds to the hybrid ILT optimization approach, which includes the selected ILT optimization initialized with the predicted ILT mask design 822. The graph 824 shows that the hybrid ILT optimization approach provides a sustained advantage over the selected ILT optimization. That is, the hybrid ILT optimization approach provides lesser loss values than the selected ILT optimization, even as more iterations are performed.

Moreover, the graph 824 shows that the hybrid ILT optimization approach achieves a given loss value significantly quicker than the selected ILT optimization. By way of example, the selected ILT optimization achieves a loss value of approximately 200 after approximately 40 iterations of the selected ILT optimization initialized with the target mask design 820 (see the dashed lines). In contrast, the hybrid ILT optimization approach achieves a loss value of approximately 200 after only approximately 10 iterations of the selected ILT optimization initialized with the predicted ILT mask design 822. Thus, the hybrid ILT optimization approach provides the same loss value but in about a quarter of the time.

The hybrid ILT optimization approach provides this advantage because using the predicted ILT mask design 822 to initialize the selected ILT optimization, instead of the target mask design 820, starts the selected ILT optimization with a mask design that, in effect, has the benefit of some optimization, by virtue of the ML ILT model, already been performed on the target mask design 820, but without actually performing the selected ILT optimization on the target mask design 820. Thus, the prediction of an ILT mask design by the ML ILT model effectively replaces iterations of the selected ILT optimization that would be performed if the selected ILT optimization were initialized with the target mask design 820.

FIG. 8G illustrates a target mask design 830 and a predicted ILT mask design 832 output by a ML ILT model based on the target mask design 830. FIG. 8G illustrates a mask design 836 generated by a selected ILT optimization of the target mask design 830. FIG. 8G illustrates a mask design 838 generated by a hybrid ILT optimization approach disclosed herein. The mask design 838 is the result of a selected ILT optimization initialized with the predicted ILT mask design 832. In contrast, the mask design 836 is the result of a selected ILT optimization initialized with the target mask design 830.

FIG. 8H illustrates a graph 834 representing loss achieved by an optimization as more iterations of that optimization are performed. The line 833 corresponds to the selected ILT optimization initialized with the target mask design 830. The line 835 corresponds to the hybrid ILT optimization approach, which includes the selected ILT optimization initialized with the predicted ILT mask design 832. The graph 834 shows that the hybrid ILT optimization approach provides a sustained advantage over the selected ILT optimization. That is, the hybrid ILT optimization approach provides lesser loss values than the selected ILT optimization, even as more iterations are performed.

Moreover, the graph 834 shows that the hybrid ILT optimization approach achieves a given loss value significantly quicker than the selected ILT optimization. By way of example, the selected ILT optimization achieves a loss value of approximately 200 after approximately 60 iterations of the selected ILT optimization initialized with the target mask design 830 (see the dashed lines). In contrast, the hybrid ILT optimization approach achieves a loss value of approximately 200 after only approximately 25 iterations of the selected ILT optimization initialized with the predicted ILT mask design 832. Thus, the hybrid ILT optimization approach provides the same loss value but in about 40% of the time.

The hybrid ILT optimization approach provides this advantage because using the predicted ILT mask design 832 to initialize the selected ILT optimization, instead of the target mask design 830, starts the selected ILT optimization with a mask design that, in effect, has the benefit of some optimization, by virtue of the ML ILT model, already been performed on the target mask design 830, but without actually performing the selected ILT optimization on the target mask design 830. Thus, the prediction of an ILT mask design by the ML ILT model effectively replaces iterations of the selected ILT optimization that would be performed if the selected ILT optimization were initialized with the target mask design 830.

FIG. 8I illustrates a target mask design 840 and a predicted ILT mask design 842 output by a ML ILT model based on the target mask design 840. FIG. 8I illustrates a mask design 846 generated by a selected ILT optimization of the target mask design 840. FIG. 8I illustrates a mask design 848 generated by a hybrid ILT optimization approach disclosed herein. The mask design 848 is the result of a selected ILT optimization initialized with the predicted ILT mask design 842. In contrast, the mask design 846 is the result of a selected ILT optimization initialized with the target mask design 840.

FIG. 8J illustrates a graph 804 representing loss achieved by an optimization as more iterations of that optimization are performed. The line 843 corresponds to the selected ILT optimization initialized with the target mask design 840. The line 845 corresponds to the hybrid ILT optimization approach, which includes the selected ILT optimization initialized with the predicted ILT mask design 842. The graph 844 shows that the hybrid ILT optimization approach provides a sustained advantage over the selected ILT optimization. That is, the hybrid ILT optimization approach provides lesser loss values than the selected ILT optimization, even as more iterations are performed.

Moreover, the graph 844 shows that the hybrid ILT optimization approach achieves a given loss value significantly quicker than the selected ILT optimization. By way of example, the selected ILT optimization achieves a loss value of approximately 300 after approximately 80 iterations of the selected ILT optimization initialized with the target mask design 840 (see the dashed lines). In contrast, the hybrid ILT optimization approach achieves a loss value of approximately 300 after only approximately 20 iterations of the selected ILT optimization initialized with the predicted ILT mask design 842. Thus, the hybrid ILT optimization approach provides the same loss value but in about a quarter of the time.

The hybrid ILT optimization approach provides this advantage because using the predicted ILT mask design 842 to initialize the selected ILT optimization, instead of the target mask design 840, starts the selected ILT optimization with a mask design that, in effect, has the benefit of some optimization, by virtue of the ML ILT model, already been performed on the target mask design 840, but without actually performing the selected ILT optimization on the target mask design 840. Thus, the prediction of an ILT mask design by the ML ILT model effectively replaces iterations of the selected ILT optimization that would be performed if the selected ILT optimization were initialized with the target mask design 840.

FIG. 8K illustrates a target mask design 850 and a predicted ILT mask design 852 output by a trained ML ILT model based on the target mask design 850. FIG. 8K illustrates a mask design 856 generated by a selected ILT optimization of the target mask design 850. FIG. 8K illustrates a mask design 858 generated by a hybrid ILT optimization approach disclosed herein. The mask design 858 is the result of a selected ILT optimization initialized with the predicted ILT mask design 852. In contrast, the mask design 856 is the result of a selected ILT optimization initialized with the target mask design 850.

FIG. 8L illustrates a graph 854 representing loss achieved by an optimization as more iterations of that optimization are performed. The line 853 corresponds to the selected ILT optimization initialized with the target mask design 850. The line 855 corresponds to the hybrid ILT optimization approach, which includes the selected ILT optimization initialized with the predicted ILT mask design 852. The graph 854 shows that the hybrid ILT optimization approach provides a sustained advantage over the selected ILT optimization. That is, the hybrid ILT optimization approach provides lesser loss values than the selected ILT optimization, even as more iterations are performed.

Moreover, the graph 854 shows that the hybrid ILT optimization approach achieves a given loss value significantly quicker than the selected ILT optimization. By way of example, the selected ILT optimization achieves a loss value of approximately 300 after approximately 180 iterations of the selected ILT optimization initialized with the target mask design 850 (see the dashed lines). In contrast, the hybrid ILT optimization approach achieves a loss value of approximately 300 after only approximately 40 iterations of the selected ILT optimization initialized with the predicted ILT mask design 852. Thus, the hybrid ILT optimization approach provides the same loss value but in about one fifth of the time.

The hybrid ILT optimization approach provides this advantage because using the predicted ILT mask design 852 to initialize the selected ILT optimization, instead of the target mask design 850, starts the selected ILT optimization with a mask design that, in effect, has the benefit of some optimization, by virtue of the ML ILT model, already been performed on the target mask design 850, but without actually performing the selected ILT optimization on the target mask design 850. Thus, the prediction of an ILT mask design by the ML ILT model effectively replaces iterations of the selected ILT optimization that would be performed if the selected ILT optimization were initialized with the target mask design 850.

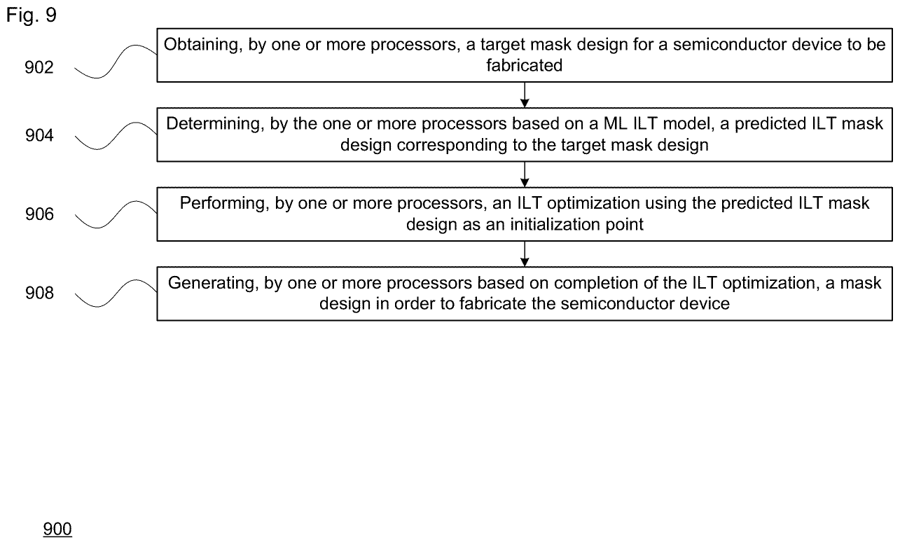

FIG. 9 illustrates an example method 900 in accordance with the above discussion. The method 900 includes, at block 902, obtaining, by one or more processors, a target mask design for a semiconductor device to be fabricated. At block 904, the method 900 includes determining, by the one or more processors based on a machine learning inverse lithography technology (ML ILT) model, a predicted ILT mask design corresponding to the target mask design. At block 906, the method 900 includes performing, by one or more processors, an ILT optimization using the predicted ILT mask design as an initialization point. At block 908, the method 900 includes generating, by one or more processors based on completion of the ILT optimization, a mask design in order to fabricate the semiconductor device.

Although the technology herein has been described with reference to particular embodiments and configurations, it is to be understood that these embodiments and configurations are merely illustrative of the principles and applications of the present technology. It is therefore to be understood that numerous modifications may be made to the illustrative embodiments and configurations, and that other arrangements may be devised without departing from the spirit and scope of the present technology as defined by the appended claims.

1. A method comprising:
obtaining, by one or more processors, a target mask design for a semiconductor device to be fabricated;
determining, by one or more processors based on a machine learning inverse lithography technology (ML ILT) model, a predicted ILT mask design corresponding to the target mask design;
performing, by one or more processors, an ILT optimization using the predicted ILT mask design as an initialization point; and
generating, by one or more processors based on completion of the ILT optimization, a mask design in order to fabricate the semiconductor device.

2. The method of claim 1, further comprising determining, by one or more processors, a mask pattern based on the mask design by simulating one or more lithographic processes.

3. The method of claim 1, further comprising training, by one or more processors, the ML ILT model using a set of target mask designs and a set of mask designs based on the ILT optimization.

4. The method of claim 3, wherein the set of target mask designs includes one or more mask designs from a standard cell library.

5. The method of claim 3, wherein the set of target mask designs includes one or more augmented mask designs based on a standard cell library.

6. The method of claim 3, wherein training the ML ILT model includes:
determining, by one or more processors based on the ML ILT model, another predicted ILT mask design corresponding to a given target mask design of the set of target mask designs; and
determining, by one or more processors, a level of difference between the other predicted ILT mask design and a given mask design of the set of mask designs corresponding to the given target mask design.

7. The method of claim 6, further comprising determining, by one or more processors, whether the level of difference exceeds a threshold level of difference.

8. The method of claim 7, further comprising, responsive to determining that the level of difference does not exceed the threshold level of difference, determining, by one or more processors, that the ML ILT model is fully trained.

9. The method of claim 1, wherein the semiconductor device is a component of an integrated circuit (IC) device.

10. The method of claim 1, wherein the semiconductor device is a component of at least one of a microelectromechanical systems (MEMS) device, a photonic device or a display device.

11. A system, comprising:
memory configured to store at least one of a machine learning inverse lithography technology (ML ILT) model and a target mask design for a semiconductor device to be fabricated; and
one or more processors operatively coupled to the memory, the one or more processors being configured to:
determine, based on the ML ILT model, a predicted ILT mask design corresponding to the target mask design;
perform an ILT optimization using the predicted ILT mask design as an initialization point; and
generate, based on completion of the ILT optimization, a mask design in order to fabricate the semiconductor device.

12. The system of claim 10, wherein the one or more processors are further configured to:
simulate one or more lithographic processes using the mask design; and
determine a mask pattern based on the simulation of the one or more lithographic processes.

13. The system of claim 10, wherein:
the memory is further configured to store a set of target mask designs and a set of mask designs based on the ILT optimization, and
the one or more processors are further configured to train the ML ILT model using the set of target mask designs and the set of mask designs.

14. The system of claim 13, wherein the set of target mask designs includes one or more mask designs from a standard cell library.

15. The system of claim 13, wherein the set of target mask designs includes one or more augmented mask designs based on a standard cell library.

16. The system of claim 13, wherein the one or more processors are configured to train the ML ILT model by being configured to:
determine, based on the ML ILT model, another predicted ILT mask design corresponding to a given target mask design of the set of target mask designs; and
determine a level of difference between the other predicted ILT mask design and a given mask design of the set of mask designs corresponding to the given target mask design.

17. The system of claim 16, wherein the one or more processors are further configured to determine whether the level of difference exceeds a threshold level of difference.

18. The system of claim 17, wherein the one or more processors are further configured to, responsive to a determination that the level of difference does not exceed the threshold level of difference, determine that the ML ILT model is fully trained.

19. The system of claim 11, wherein the semiconductor device is a component of an integrated circuit (IC) device.

20. The system of claim 11, wherein the semiconductor device is a component of at least one of a microelectromechanical systems (MEMS) device, a photonic device or a display device.
